(19) United States
(12) Patent Application Publication
(10) Pub. No.: US 2015/0034481 A1
(43) Pub. Date: Feb. 5, 2015

(54) FASTENING MEMBER AND VACUUM DEVICE

(71) Applicant: CANON ANELVA CORPORATION, Kawasaki-shi (JP)

(72) Inventor: Shigenori ISHIHARA, Kawasaki-shi (JP)

(21) Appl. No.: 14/481,978

(22) Filed: Sep. 10, 2014

Related U.S. Application Data
(63) Continuation of application No. PCT/JP2012/005778, filed on Sep. 12, 2012.

(30) Foreign Application Priority Data
Mar. 14, 2012 (JP) 2012-057301

(51) Int. Cl. H01J 37/34

(52) U.S. Cl. CPC H01J 37/3411; H01J 2237/332
USPC 204/298.11

(57) ABSTRACT

The present invention provides a fastening member which involves only a low risk of contamination even after repeatedly performing a detachment operation, and to provide a vacuum device including it. One embodiment is a fastening member comprising: a head section including a head-upper-face portion, a seating face portion, and a head-side-face portion; and a shaft section and including a threaded portion on an end portion thereof on the opposite side from the head section, wherein the threaded portion is given hardness higher than at least those of the other portions of the fastening member, and when the member is attached to the inner wall of the chamber with the fastening member, the threaded portion is threadedly engaged with an internally threaded portion provided in the inner wall of the chamber, and the sealing face portion presses the member against the inner wall of the chamber.

### CROSS-REFERENCES TO RELATED APPLICATIONS

This application is a continuation application of International Application No. PCT/JP2012/005778, filed Sep. 12, 2012, which claims the benefit of Japanese Patent Application No. 2012-057301, filed Mar. 14, 2012. The contents of the aforementioned applications are incorporated herein by reference in their entireties.

### TECHNICAL FIELD

The present invention relates, in a vacuum device configured to perform a film forming process on a processing target substrate under vacuum, to a fastening member for attaching a member to the inner wall of the chamber of the vacuum device and to the vacuum device.

### BACKGROUND ART

Conventionally, film forming devices have been used to perform film forming processes on processing target substrates such as silicon wafers, liquid crystal display substrates, optical discs, and MiniDiscs in various types of manufacturing processes such as semiconductor manufacturing processes, liquid crystal display panel manufacturing processes, and disc manufacturing processes.

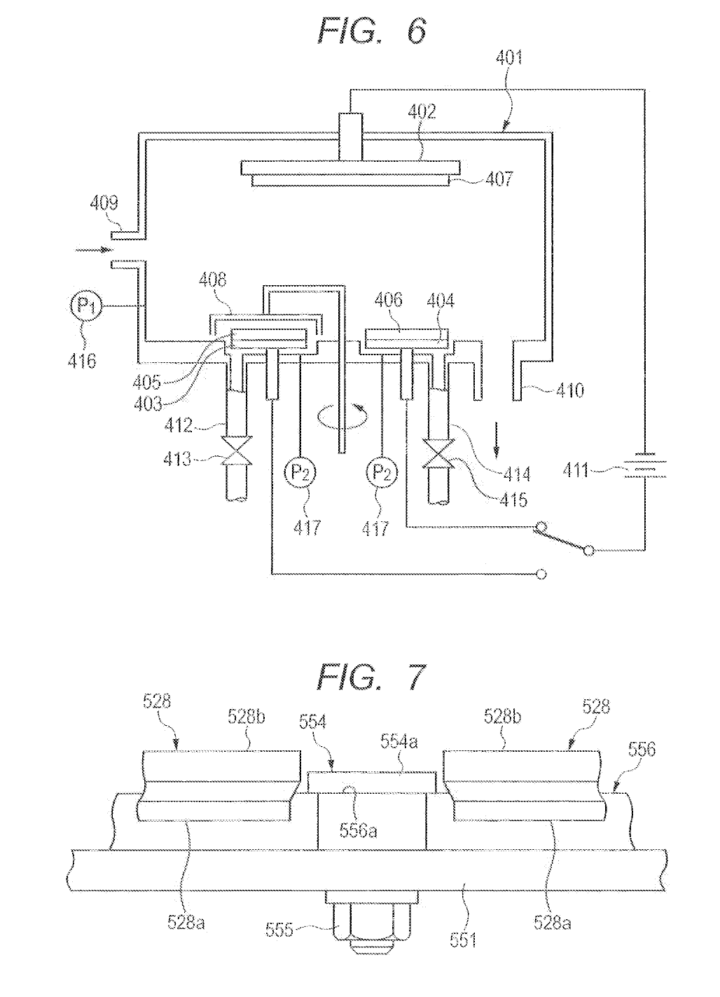

FIG. 6 is a schematic view of a sputtering device used as one example of such a film forming device (see Patent Document 1). The film forming device illustrated in FIG. 6 is configured such that a pressure P2 of a gas to be supplied to the inner side of a shutter 408 covering an unused target 405 is made to always maintain a relationship of P2>P1 with a pressure P1 of a sputtering gas; in this way, the gas flows into a vacuum chamber 401 from the inner side of the shutter 408 covering the unused target 405, making it possible to prevent a mixed gas from flowing in from the sputtering atmosphere and contacting the surface of the unused target. Note that in the device in FIG. 6, reference numerals 412, 414 denote gas supplying nozzles for supplying a contamination preventing gas into a space between the target 405 and the shutter 408 and into a space between a target 406 and the shutter 408, respectively; reference numerals 413, 415 denote gas supplying valves configured to control the amounts of the gas to be supplied from the gas supplying nozzles 412, 414, respectively; reference numeral 416 denotes a pressure gauge configured to measure the pressure of the gas inside the vacuum chamber; and reference numeral 417 denotes pressure gauges each configured to measure the pressure of the inner side covered with tire shutter 408 (hereinafter referred to as the target chamber).

Here, since atoms and molecules emitted from the targets 405, 406 fly in random directions, a film is deposited on unwanted areas such as the inner wall of the vacuum chamber 401. As the process is repeated, the deposited film accumulates and is eventually separated, thereby adversely affecting the quality of the film formation. This creates a need for removal via regular maintenance.

For this reason, film forming devices usually use a part called a shield to define a film forming space from each target 405, 406 to a substrate 407, and this shield is regularly replaced to achieve a stable film forming quality. The film forming device in FIG. 6 uses a shield to partition a space in the vicinity of each target 405, 406 and in the vicinity of the substrate 407 to prevent deposition of a sputtered film onto the wall of the vacuum chamber 401.

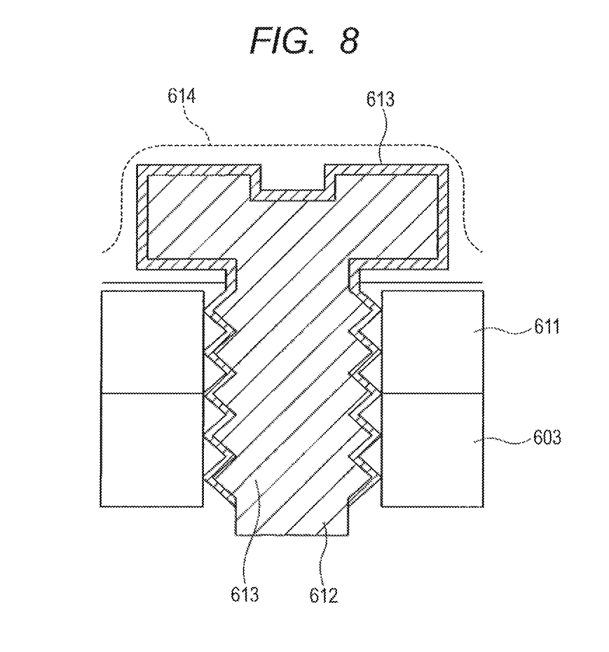

For the fixing of these shield and shutter parts, a structure in which they are bolted from inside the film forming space is sometimes used in light of ease in detachment and replacement. FIG. 7 is a vertical cross-sectional view illustrating a shield fastening structure in which a shield is fastened from inside a film forming space (see Patent Document 2). In the shield fastening structure illustrated in FIG. 7, a second deposition preventing plate 556 is provided on a center area of the front face of a first deposition preventing plate 551, which is surrounded by substrate holders 528, in a detachable manner by means of a second-deposition-preventing-plate attaching bolt 554 and nut 555. A front face 556a of the second deposition preventing plate 556 is positioned at a level between a front face 528b and a back face 528a of each substrate holder 528. This provides a structure in which target atoms cannot easily flow to the back face 528a side of each substrate holder 528 through a gap between the second deposition preventing plate 556 and the substrate holder 528. Meanwhile, a bolt head section 554a of the bolt 554 is exposed to the film forming space, and the sputtered film is therefore deposited thereon. Thus, like the shield, the bolt head 554a is often processed by a blasting process or a thermal spraying process to increase its surface roughness. Note that for maintenance, one can access these parts from the film forming space and perform a replacement operation.

In general, stainless steel is often employed as the material of the bolt used in such a structure for its good commercial availability and good corrosion resistance. However, among metals, stainless steel has low thermal conductivity and a large coefficient of thermal expansion. Thus, a phenomenon called galling is likely to occur in which external and internal threads adhere and immovably fixed to each other due to frictional heat generated in the threads during fastening. When this galling phenomenon occurs, fastening with the same torque results in greater friction between the threaded portions, which in turn causes a problem of a greater risk of particle generation.

As a technique to prevent galling of threaded portions as described above, the technique of coating the threaded portions with lubricant that reduces the coefficient of friction has been widely used. Here, in a case of coating grease. Teflon (registered trademark), or the like inside a vacuum device, there is a risk that the coating layer may be degassed and contaminate the film forming environment. For this reason, coating of a soft metal, such as silver, which has a lubricating function and also produces only a small amount of volatilized gas under vacuum has often been used.

By applying solid lubricating means such as sliver plating to the threaded portions, and further by giving the bolt head section greater surface roughness than its base material by a blasting process or the like, a shield fastening structure suppressing particle generation can be obtained.

In the above-described shield fastening structure, particle generation does not occur when the shield is fastened with a new bolt and a new threaded hole. However, as a bolt that has once been fastened is removed for replacement of the shield, the silver plating is easily separated. Thus, as the shield replacement operation is repeated, the separated silver accumulates in the internally threaded portion or floats in the film forming space and eventually causes contamination such as adhesion to the processing target object.

Meanwhile, Patent Document 3 discloses a shield fastening structure in which a shield and an entire bolt are coated with molybdenum. FIG. 8 is a cross-sectional view illustrating the shield fastening structure in Patent Document 3. According to Patent Document 3, a shield plate 611 and a bolt 612 for fixing the shield plate 611 are coated with a molybdenum film 613. Thus, with the molybdenum coating, an aluminum film 614 deposited on the surface of the shield plate 611 and on the head session of the bolt 612 can be easily removed. Accordingly, the bolt can be accessed by a tool in a shorter time and in addition, the ease in detachment can be improved by the coating of the threaded portion.

### CITATION LIST

### Patent Document

Patent Document 1: Japanese Patent Application Laid-Open No. Hei 04-202768

Patent Document 2: Japanese Patent Application Laid-Open No. Hei 11-092913

Patent Document 3: Japanese Patent Application Laid-Open No. Hei 08-041637

### SUMMARY OF INVENTION

However, there is also a problem in the shield fastening structure in Patent Document 3 in that the coating film itself has a risk of becoming a source of contamination as the shield replacement operation is repeated. There is another problem in the shield fastening structure in Patent Document 3 in that although the film removal from the head section of the bolt 612 can be done more easily, there is, at the same time, a greater risk of the deposited film falling from the head section of the bolt 612 into the sputtering device while the sputtering device is in use. However, no solution to these problems has been known.

The present invention has been made in view of the above-described problems, and an object thereof is to provide a fastening member which involves only a low risk of contamination even after repeatedly performing a detachment operation, and to provide a vacuum device including the fastening member.

For achieving the above-mentioned object; one aspect of the present invention provides a fastening member for attaching a member to an inner wall of a chamber of a vacuum device, comprising: a head section including a head-upper-face portion, a seating face portion opposed to the head-upper-face portion, and a head-side-face portion forming a side wall between the head-upper-face portion and the seating face portion; and a shaft section provided on the seating face portion side of the head section and including a threaded portion on an end portion thereof on the opposite side from the head section, wherein the threaded portion is given higher hardness than at least those of other portions of the fastening member, and when the member is attached to the inner wall of the chamber with the fastening member, the threaded portion is threadedly engaged with an internally threaded portion provided in the inner wall of the chamber, and the seating face portion presses the member against the inner wall of the chamber.

In the fastening member according to the present invention, the threaded portion of the fastening member is given higher hardness than at least those of other portions of the fastening member. Thus, when the member is attached to the inner wall of the chamber with the fastening member, it is possible to suppress wear resulting from friction between the threaded portion and the internally threaded portion. At the same time, the threaded portion given the higher hardness has a lower coefficient of thermal expansion than that of the base material of the fastening member, thereby suppressing the thermal expansion itself. Accordingly, it is possible to reduce generation of particles from the threaded portion resulting from detachment and attachment operations of the fastening member.

BRIEF DESCRIPTION OF DRAWINGS

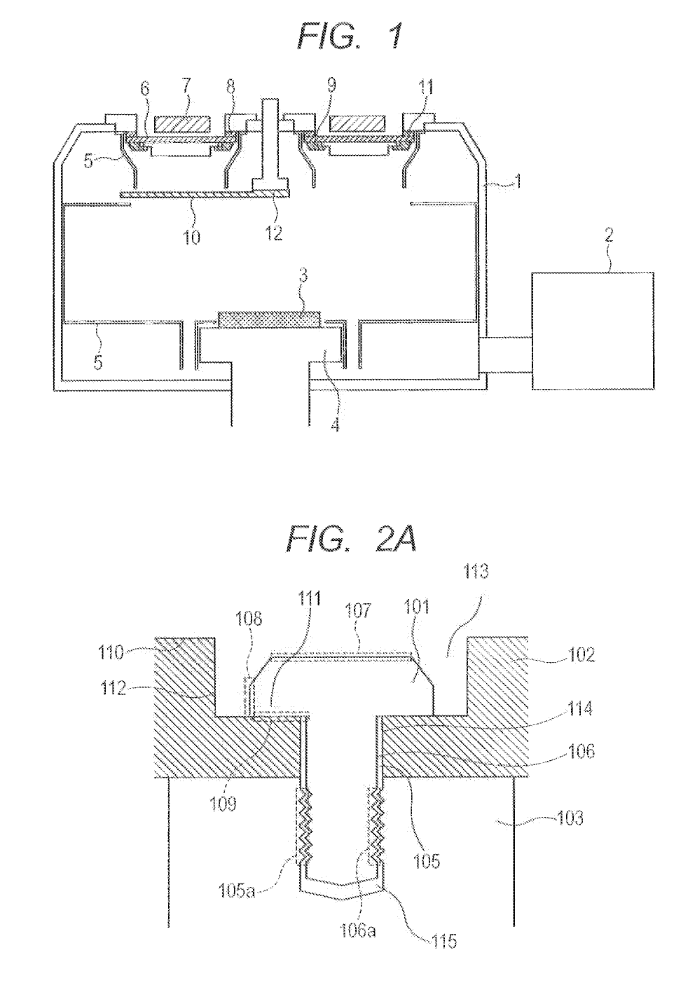

FIG. 1 is a schematic view illustrating the structure of a film forming device including a fastening member according to one embodiment of the present invention.

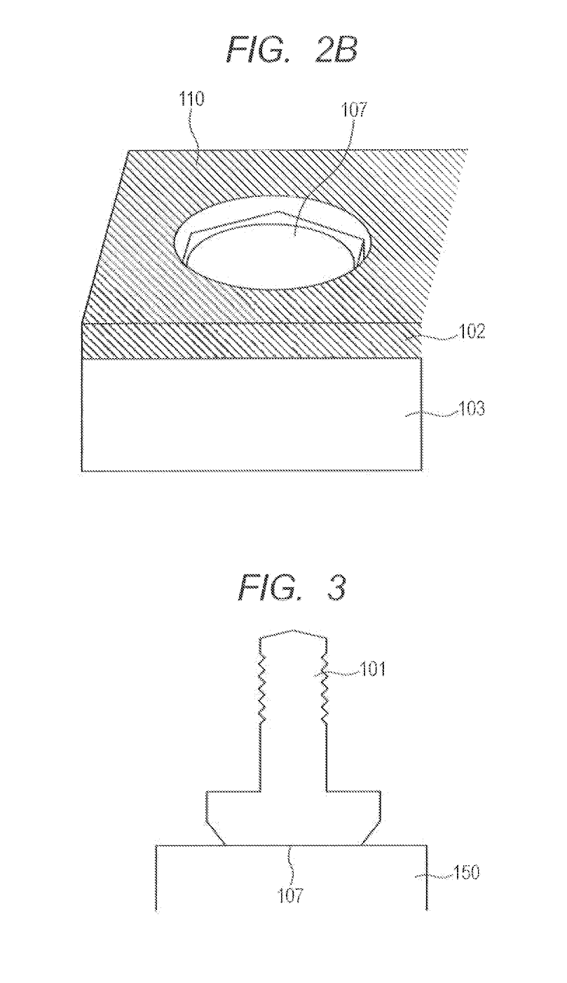

FIG. 2A is a cross-sectional view of the fastening member according to the one embodiment of the present invention.

FIG. 2B is a perspective view of the fastening member according to the one embodiment of the present invention.

FIG. 3 is a view illustrating an overview of a partial surface hardening process in the one embodiment of the present invention.

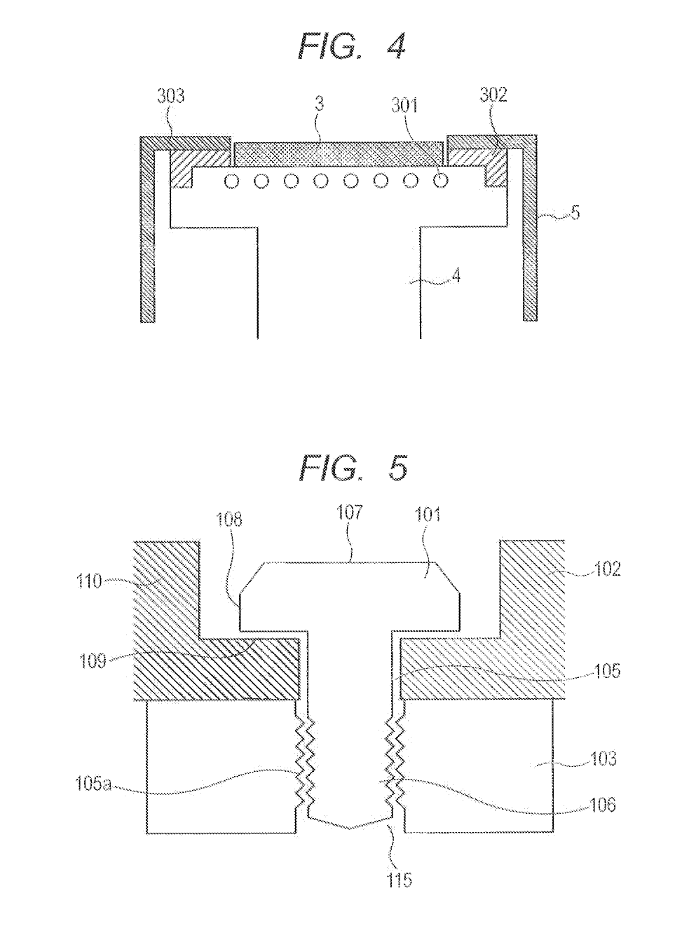

FIG. 4 is a schematic view illustrating the structure of another film forming device including the fastening member according to the one embodiment of the present invention.

FIG. 5 is a cross-sectional view of a fastening member according to another embodiment of the present invention.

FIG. 6 is a view illustrating a shield fastening structure in one exemplary conventional technique (Patent Document 1).

FIG. 7 is a view illustrating a shield fastening structure in one exemplary conventional technique (Patent Document 2).

FIG. 8 is a view illustrating a shield fastening structure in one exemplary conventional technique (Patent Document 3).

### DESCRIPTION OF EMBODIMENTS

Hereinbelow, the contents of the present invention will be described in detail with reference to drawings. FIG. 1 is a schematic view illustrating the structure of a sputtering device which is one example of a vacuum device (e.g. a film forming device) including a fastening member of the present invention. In this device, evacuating means 2 such as a turbomolecular pump is connected to a vacuum chamber 1 made of stainless steel or the like and capable of maintaining a high vacuum environment of, for example, 1×10⁻³ Pa therein. Further, the vacuum chamber 1 includes a holder 4 configured to hold a processing target substrate 3, and the processing target substrate 3 is mounted thereon to be subjected to a film forming process. Reference numeral 6 denotes a target made of a pure substance or a compound thereof as the raw material for the film formation. The target 6 is connected to an unillustrated DC power source so that voltage can be applied thereto. The target 6 is placed with an insulator 8 made of alumina or the like thereon so as to be electrically insulated from the vacuum chamber 1. Further, a magnet 7 is provided so that a magnetic field can be applied to the surface of the target 6.

Vacuum devices to which the fastening member of the present invention is applicable are not limited to the one described in this embodiment; physical vapor deposition device, chemical vapor deposition (CVD) devices, atomic layer deposition (ALD) devices, and the like are available.

Unillustrated gas introducing means for supplying a sputtering gas such for example as argon is connected to the vacuum chamber 1. By evacuating the vacuum chamber 1 via the evacuating means 2 while introducing the gas, and also by applying power from the DC power source such that the voltage at the target 6 will be negative, the magnet causes magnetron discharge. The magnetron discharge turns the sputtering gas into plasma in the vicinity of the target 6, and positive ions in this plasma are accelerated by and collide with the target 6 at the negative voltage. By the collision of the positive ions, atoms, molecules, and the like are emitted from the target 6, and the metal thus produced reaches the front face of the substrate 3 facing it. As a result, a desired film is deposited. Further, if the gas introducing means introduces the sputtering gas with oxygen, nitrogen, or the like mixed therein, so-called reactive sputtering can be performed which allows deposition of a metal nitride film or a metal oxide film.

In the device in FIG. 1, multiple targets 6 are mounted, and the multiple targets 6 can be switched and used by means of a drivable shutter 10. Thus, it is possible to stack and form multiple types of films in one chamber.

Meanwhile, since the atoms and molecules emitted from each target 6 fly in random directions, a film is deposited on unwanted areas such as the inner wall of the vacuum chamber 1. As the process is repeated, the deposited film accumulates and is eventually separated, thereby adversely affecting the quality of the film formation. This creates a need for removal via regular maintenance.

For this reason, film forming devices usually use a part called a shield to define a film forming space from each target to a processing target object, and this shield is regularly replaced to achieve a stable film forming quality. In FIG. 1, shields 5, 9 are used to partition a space in the vicinity of each target and in the vicinity of the processing target substrate 3 to prevent deposition of a sputtered film on the wall of the vacuum chamber 1. Consequently, the sputtered film is deposited on the shields 5 and the shutter 10, and therefore maintenance is regularly performed to detach and replace them with new ones. Meanwhile, a process such as a blasting process or thermal spraying is performed on the surfaces of the shields 5, 9 and the shutter 10 to increase their surface roughness such that the ten-point mean roughness (Rz) will be, for example, 10 μm or greater. This feature prevents the deposited film from being separated easily.

FIG. 2A is a cross-sectional view of a fastening member used in a vacuum film forming device in one exemplary embodiment of the present invention. Moreover, FIG. 2B is a perspective view of the fastening member in the one exemplary embodiment of the present invention. The vacuum film forming device is, for example, the sputtering device illustrated in FIG. 1 and, in particular, uses the fastening member illustrated in FIGS. 2A and 2B as each of the fastening members for the shields 5, 9 and the shutter 10 (denoted by reference numerals 11, 12, respectively) in FIG. 1.

The fastening member illustrated in FIGS. 2A and 2B is a fastening member for attaching a fixing target member 102 (e.g. the shield 5, 9) to the inner wall of the chamber 1 of the vacuum device illustrated in FIG. 1, and is formed of a shaft section 106 and a head section 101. The head section 101 includes a head-upper-face portion 107, a seating face portion 111 opposed to the head-upper-face portion 107, and a head-side-face portion 108 forming a side wall between the head-upper-face portion 107 and the seating face portion 111. The shaft section 106 is provided on the seating face portion 111 side of the head section 101 and includes a threaded portion (externally threaded portion) 106a on an end portion thereof on the opposite side from the head section 101. The threaded portion 106a is given higher hardness than at least those of other portions of the fastening member. Note that the higher hardness may be given to the head-side-face portion 108 and the seating face portion 111. The higher hardness is given to the fastening member by a surface hardening process. Further, at least the head-upper-face portion 107 is preferably subjected to a surface roughening process which gives surface roughness equal to or greater than that of the seating face portion 111. Furthermore, at least the head-upper-face portion 107 is preferably subjected to a surface roughening process which gives surface roughness equal to or greater than a ten-point mean roughness (Rz) of 10 μm.

A fixing part 103 including an internally threaded hole 115 is provided on the inner wall of the chamber 1 at a position at which a fixing target member 102 should be fixed. An internally threaded portion 105a threadedly engageable with the threaded portion 106a is formed on the inner wall face of the internally threaded hole 115. To attach the fixing target member 102 to the fixing part 103 with the fastening member, the threaded portion 106a is threadedly engaged with the internally threaded portion 105a, and they are fixed such that the seating face portion 111 presses the fixing target member 102 against the fixing part 103.

In this embodiment, the fixing target member 102 is a shield part 102 provided inside the vacuum chamber 1 illustrated in FIG. 1 and configured to capture a depositing material resulting from thin film formation. The shield part 102 includes a shield face 112 surrounding the head-side-face portion 108, a through-hole 105 for inserting the fastening member such that the shield part 102 can be fixed to the vacuum chamber 1 with the fastening member, and a counterbore face 109 facing the seating face portion 111. The through-hole 105 is formed of a first hole portion 113 forming the shield face 112 and being larger than the head section 101, and a second hole portion 114 having an opening at the counterbore face 109, communicating with the first hole portion 113, and provided in a size that is smaller than that of the head section 101 and allows the shaft section 106 to penetrate therethrough. The shield face 112 extends toward the upper face of the fastening member beyond the upper end of the head-side-face portion 108. Thus, a front face 110 of the shield part 102 is situated higher than the head-side-face portion 108. That the head-side-face portion 108 does not protrude from the shield face 112, therefore, suppresses deposition of a film onto the head-side-face portion 108 which has been subjected to the hardening process but not to the surface roughening process. In this way, when the fastening member is detached by using a tool, it is possible to suppress the occurrence of falling of the deposited film from the head-side-face portion 108. Accordingly, the reliability of the device can be improved.

The fastening member is, for example, a hexagonal head bolt made of a stainless steel SUS316L with the threaded portion 106a measuring 5 mm in outer diameter. By being connected to the internally threaded portion 105a provided in the fixing part 103, which is likewise made of SUS316L, via the through-hole (the first hole portion 113, the second hole portion 114) provided in the shield part 102, the hexagonal head bolt applies force in a compressing direction to and thus fastens the shield part 102. To fasten or detach the shield part 102, such an operation is performed by connecting, for example, a hexagonal wrench to the head-side-face portion 108. Note that the shield part 102 is attached to the inner wall of the chamber 1 with the fixing part 103 therebetween in FIG. 2A. However, the internally threaded hole 115 and the internally threaded portion 105a may be formed in the inner wall of the chamber 1 (a portion thereof corresponding to the fixing part 103 in FIG. 2A) and the shield part 102 may be directly attached thereto with the fastening member without the fixing part 103 therebetween. Moreover, a publicly known nut or the like may be used as the internally threaded portion 105a.

Here, the internally threaded hole 115 provided in the fixing part 103 which fastens to the shield part 102 may not be in a concave shape as illustrated in FIG. 2A, but may be a through-hole (penetrating hole) instead. This case is more preferable because debris resulting from wear is less likely to accumulate in the internally threaded hole 115. FIG. 5 is a cross-sectional view of the fastening member in the case where the internally threaded hole 115 illustrated in FIG. 2A is switched to a through-hole (penetrating hole). The shapes of the other portions are the same as those in FIG. 2A. In the case of FIG. 5, even if debris is produced from the threaded portion 106a or the internally threaded portion 105a, it will not accumulate in the internally threaded hole 115 and can be discharged to the outside of the film forming space because the internally threaded hole 115 is a through-hole (penetrating hole). Accordingly, the reliability of the film forming device can be improved.

As the surface hardening process, formation of a hardened layer on the stainless steel with a gradient by a carbon doping process (or a so-called carburizing process) may be employed. In this way, it is possible to perform a surface hardening process without separation even after multiple fastening and detaching operations. In this embodiment, the carburizing processing is performed on the head-side-face portion 108, the threaded portion 106a, and the seating face portion 111 of the bolt head section of the fastening member, as well as on the internally threaded portion 105a of the fixing part 103. As a result of the doping of carbon with a concentration gradient changing in the depth direction, the Vickers hardness (hereinafter referred to as HV) of the surface is improved to, for example, about a HV of 700 as compared to the HV of the base material, or 3US316L, which is 200.

As the surface hardening process, a nitriding process or an anti-wear coating process can be used besides the carburizing process used in this embodiment. The coating process is a process in which a film made of a different material than the base material is formed on the surface; publicly known ion plating, sputtering, or the like can be used, and various types of films such as those of TiN are available as the coating film.

Note, however, that the anti-wear coating mentioned here refers to one that involves formation of a strong film on a coated surface to improve the hardness, and not to those that involve adhesion of part of a coated film to the counterpart (adhesion of a coated film to an internally threaded portion in a case where its externally threaded portion is coated therewith) as in a case of using a so-called solid lubricant such as the molybdenum coating used in Patent Document 3, silver platings or fluorine coating. Such anti-wear coating is less likely to become a source of contamination and is therefore preferable.

As the carburizing process, for example, a publicly known plasma carburizing process is used. In this embodiment, during the carburizing process, the process is performed with the head-upper-face portion 107 of the head section 101 set in close contact with a stainless part 150 so as to be masked as illustrated in FIG. 3. In this way, the hardness of the portions of the fastening member other than the head-upper-face portion 107 can be enhanced by the carburizing process. On the other hand, the head-upper-face portion 107 can be prevented from being doped with carbon, and therefore the hardness of the upper face portion 107 is not enhanced and can be maintained at an equivalent level to that of the base material.

With the hardness of the threaded portion 106a, the head-side-face portion 108, the seating face portion 111, and the internally threaded portion 105a improved to higher hardness, it is possible to suppress wear resulting from friction between members when the shield part 102 and the fixing part 103 are attached with the fastening member. Moreover, by the improvement to higher hardness, the coefficient of thermal expansion decreases below that of the base material. Thus, the thermal expansion itself is suppressed as well. Accordingly, it is possible to reduce generation of particles resulting from detachment and attachment operations of the fastening member.

After the surface hardening process, a roughening process such as alumina blasting is performed on the head-upper-face portion 107 of the head section 101 so that its surface roughness can be equal to or greater than the surface roughness of the seating face portion 111, e.g. an arithmetical mean roughness (Ra) of 3.5 μm and a ten-point mean roughness (Pz) of 20 μm. Performing, on the head-upper-face portion 107, a surface roughening process which gives surface roughness equal to or greater than a ten-point mean roughness (Rz) of 10 μm or greater as described above brings about an advantageous effect of making the deposited film on the head-upper-face portion 107 separated less easily therefrom, and thereby improving the reliability of the device. In general, the higher the hardness of a processing target surface, the less efficient its surface roughening process becomes. However, in this embodiment, as illustrated in FIG. 3, the head-upper-face portion 107 is protected from the carburization during the carburizing process. Thus, the hardness of the head-upper-face portion 107 is maintained at a HV of 200 which is substantially equal to that of the base material. Accordingly, surface roughness necessary for preventing separation of the deposited film can be obtained in an efficient and highly reproducible manner.

As the blasting process, various blasting methods such as one using glass beads, silicon carbide, dry ice, or the like are available besides alumina blasting.

If the surface hardening process is performed after the surface roughening process, the surface roughness formed by the surface roughening process would be decreased by the surface hardening process. However, in this embodiment, the surface roughening process (blasting process) is performed after the surface hardening process, which brings about an advantageous effect of making the surface roughness formed by the surface roughening process decrease less easily. Moreover, since the surface roughening process is performed by using a publicly known blasting process, the necessary surface roughness can be obtained at a low cost. Further, since the head-upper-face portion 107 is masked during the surface hardening process, the surface roughness obtained from the surface roughening process is increased, which brings about an advantageous effect of reducing the generation of particles.

Here, it is more preferable to also thermally spray a metal such as aluminum or titanium after the blasting process, since doing so can provide even greater surface roughness and make the deposited film less easily separated from the film forming space. For example, a surface with a ten-point mean roughness (Rz) of approximately 50 μm can be obtained by adhering pure aluminum to a thickness of about 100 μm by plasma spraying.

As the thermal spraying process, various methods such as arc spraying are available besides plasma spraying.

It is preferable to form a path for cooling with cooling water as cooling means in the vacuum chamber 1 in the vicinity of the internally threaded portion 105a. In this way, it is possible to reduce friction between the threaded portion 106a and the internally threaded portion 105a resulting from their thermal expansion, and therefore suppress generation of particles. Meanwhile, surface hardening processes are generally known to be affected by high temperature environments. For example, it is known that in a case of a carburizing process on a base material of stainless steel (e.g. SUS316), the composition of the surface phase changes at or above 400° C. and the hardness drops. Further, in a case of a coating process with TiN or the like, the risk of separation increases under a high temperature environment due to the difference in coefficient of thermal expansion from the base material. Thus, by providing the cooling means, the internally threaded portion 105a can be maintained at low temperatures, thereby making it possible to maintain the hardness of the surface of the fastening member and suppress generation of particles.

As described above, the front face 110 of the shield part 102 is positioned higher than the head-side-face portion 108 of the fastening member. Thus, deposition of a film onto the head-side-face portion 108 can be suppressed. While the shape and size of the opening of the through-hole 105 at the front face 110 of the shield part 102 may be any shape and size, a circular opening measuring 13 mm in diameter is provided here for a bolt with a hexagonal head measuring 4.6 mm in length on each side, as illustrated in FIG. 2B.

With the configuration according to this embodiment, it is possible to reduce powder resulting from wear of each of the portions that come into contact with a tool (such as the head-side-face portion 108), the seating face portion 111, the head-upper-face portion 107, the threaded portion 106a, and the internally threaded portion 105a and also to reduce falling of the deposited film therefrom even when a replacement operation of the shield part 102 is repeatedly performed. Accordingly, the reliability of the device can be improved. Further, since the hardened layer formed on the surface of the fastening member wears only to a small extent even after repeated use, the fastening member can be used repeatedly by removing the film deposited on the head-upper-face portion 107. This is effective in reducing the running cost of the device.

In this embodiment, the structure in which the shield part 102 (the shield 5, 9) is fastened with the fastening member is described. However, the same fastening structure can be used to fasten other elements (such as the shutter 10) in the chamber 1 with the fastening member.

The fastening member according to the present invention is not limited to the example described above. The shape of the bolt head, the length and pitch of the threaded portion, and other features can be any shape, length, pitch, etc.

FIG. 4 is an example of the configuration of a shield fastening structure to be mounted on the holder 4 configured to hold the processing target substrate 3 in the device in FIG. 1, the configuration being preferable when the holder 4 includes a heating mechanism.

In FIG. 4, reference numeral 301 denotes heating means such for example as a nichrome wire buried in the holder 4. Film formation is performed with the heating means being controlled at a desired temperature via unillustrated power supplying means, temperature sensor, and temperature controlling means and raising the temperature of the processing target substrate 3. Reference numeral 303 denotes a shield provided in such a way as to protect deposition of a film onto an area of the upper face of the holder 4 not covered with the processing target substrate 3 and onto the side face of the holder 4. Reference numeral 302 denotes a heat insulating part made, for example, of alumina and has such a structure as to be cable of reducing thermal conduction from the holder 4 to the shield 303. The shield 303 is fastened to the heat insulating part 302 with a fastening structure as illustrated in FIG. 2A. With such a configuration, it is possible to maintain the shield 303 and the fastening member at lower temperatures than the processing target substrate 3.

In general, the surface layer of stainless steel hardened by coating is low in coefficient of thermal expansion, which leads to cases where cracking or the like occurs under high temperature environments due to the difference in coefficient of thermal expansion from the base material. In addition, for stainless steel hardened by a carburizing process, there are cases where elimination of carbon occurs or the metallic composition of the stainless steel changes under high temperature environments, thereby causing embrittlement. Thus, by employing the configuration illustrated in FIG. 4, the temperature of the fastening member can be maintained at low temperatures. Accordingly, it is possible to extend the life of the hardened area of the surface of the fastening member and therefore achieve an effect desirable for improving the reliability of the device.

The modes of the present invention are not limited to the above embodiments, but are freely changeable within the scope of the gist of the invention. For example, the shape of the bolt is not limited to the hexagonal shape illustrated in the embodiments, but may be an octagonal shape, a quadrangle shape, or some other shape. Also, the bolt may be provided with a gas evacuating hole for evacuating air between the internally threaded portion and the externally threaded portion. Further, as for the material of the bolt, a material such as titanium or aluminum can be employed. Furthermore, the internally threaded portion may be one with a helical coil insert or the like inserted therein, or one provided with the above-mentioned gas evacuating hole.

1. A vacuum device configured to form a thin film on a substrate disposed inside a vacuum chamber, comprising:
a shield provided inside the vacuum chamber and configured to capture a depositing material resulting from the formation of the thin film; and
a fastening member for attaching the shield to an inner wall of the vacuum chamber, comprising:
a head section including a head-upper-face portion, a seating face portion opposed to the head-upper-face portion, and a head-side-face portion forming a side wall between the head-upper-face portion and the seating face portion; and
a shaft section provided on the seating face portion side of the head section and including a threaded portion on an end portion thereof on the opposite side from the head section,
wherein the shield includes:
a shield face surrounding the head-side-face portion;
a through-hole for inserting the fastening member such that the shield is fixed to the vacuum chamber with the fastening member; and
a counterbore face facing the seating face portion,
wherein the through-hole includes:
a first hole portion forming the shield face and being larger than the head section; and
a second hole portion having an opening at the counterbore face, communicating with the first hole portion, and provided in a size that is smaller than the head section and allows the shaft section to penetrate therethough,
wherein the shield face extends toward an upper face of the fastening member beyond an upper end of the head-side-face portion,
wherein the fastening member except the head-upper-face portion is subjected to a surface hardening process which gives higher hardness than that of the head-upper-face portion,
the head-upper-face portion of the fastening member is subjected to a surface roughening process which gives surface roughness, and
wherein the shield is attached to the inner wall of the chamber with the fastening member, such that the threaded portion is threadedly engaged with an internally threaded portion provided in the inner wall of the vacuum chamber, and the seating face portion presses the shield against the inner wall of the vacuum chamber.

2. (canceled)

3. (canceled)

4. The vacuum device according to claim 1, wherein a base material of the fastening member is stainless steel, and the surface hardening process is a carburizing process in which the stainless steel is hardened by doping the stainless steel with carbon.

5. The vacuum device according to claim 1, wherein the higher hardness is given to the fastening member by forming a film on a surface thereof, the film being made of a different material than the base material.

6. (canceled)

7. The vacuum device according to claim 1, wherein the surface roughness given to the head-upper-face portion is equal to or greater than surface roughness of the seating face portion.

8. The vacuum device according to claim 1, wherein the surface roughness given to the head-upper-face portion is equal to or greater than a ten-point mean roughness (Rz ) of 10 μm.

9. The vacuum device according to claim 1, wherein surface roughness is given to the head-upper-face portion by a blasting process performed after the surface hardening process.

10. The vacuum device according to claim 9, wherein a metal film is formed on the head-upper-face portion by a thermal spraying process performed after the blasting process.

11. (canceled)

12. (canceled)

13. The vacuum device according to claim 1, wherein the higher hardness is also given to the internally threaded portion provided in the inner wall of the vacuum chamber.

14. The vacuum device according to claim 1, wherein the internally threaded portion provided in the inner wall of the vacuum chamber is a through-hole.

15. The vacuum device according to claim 1, wherein cooling means for cooling the internally threaded portion is provided to the vacuum chamber.

16. The vacuum device according to claim 1, wherein the shield face extends toward the upper face of the fastening member beyond the upper end of the head-side-face portion, and a front face of the shield is located higher than the head-side-face portion.
